(19) United States
(12) Patent Application Publication
(10) Pub. No.: US 2007/0140008 A1
(43) Pub. Date: Jun. 21, 2007

(54) Independently programmable memory segments within an NMOS electrically erasable programmable read only memory array achieved by P-well separation and method therefor

(75) Inventors: Jeffrey Shields, Chandler, AZ (US); Kent Hewitt, Chandler, AZ (US); Donald Gerber, Scottsdale, AZ (US); Randy Yach, Phoenix, AZ (US)

Correspondence Address: Paul N. Katz;Baker Botts L.L.P., One Shell Plaza, 910 Louisiana Street, Houston, TX, 77002-4995, US

(73) Assignee: Microchip Technology Incorporated

(21) Appl. No.: 11/314,504

(22) Filed: Dec. 21, 2005

(51) Int. Cl. G11C 16/04; G11C 11/34

(52) U.S. Cl. 365/185.11; 365/185.18

(57) ABSTRACT

An array of N-channel memory cells may be separated into independently programmable memory segments by creating multiple, electrically isolated P-wells upon which the memory segments are fabricated. The multiple, electrically isolated P-wells may be created, for example, by p-n junction isolation or dielectric isolation.

### TECHNICAL FIELD

The present disclosure, according to one embodiment, relates to semiconductor devices, more specifically to N-channel Electrically Erasable Programmable Read Only Memory (EEPROM) (hereinafter memory) devices that may have segmented independently programmable memory sub-arrays.

### BACKGROUND

A common practice in fabricating Electrically Erasable Programmable Read Only Memory (EEPROM) was to produce N-channel cells over a P-well substrate because of a simpler manufacturing process and lower programming voltages. The approach used by Caywood; as disclosed in U.S. Pat. No. 5,986,931, entitled “Low Voltage Single Supply CMOS Electrically Erasable Read-Only Memory” which is a continuation-in-part of U.S. Pat. No. 5,790,455, and U.S. Pat. No. 5,986,931 (Caywood 2) and U.S. Pat. No. 5,790,455 (Caywood 1), incorporated by reference herein for all purposes; produces precisely the opposite configuration, i.e., P-channel devices over an N-well, which itself resides in a P-type substrate. The novelty of the Caywood approach is the reduction in magnitude of the applied voltage required for erasing and writing to the device while maintaining a similar writing speed as found in the related technology prior to Caywood as well as the elimination of certain components functionally necessary in the related technology.

Referring to FIG. 1, the N-channel memory device related technology is illustrated. Each memory transistor (MEM) required a row select transistor (SEL), which controlled the data received from the bit lines (BL). Also, if byte addressing was desired, then the device included a byte select transistor (BYTE) for every eight memory transistors. The problem solved by Caywood with the advent of a P-channel/N-well device was the elimination of the row select transistors. Even after Caywood, byte selection still required the presence of the byte select transistors. The elimination of the byte select transistors resulted in the undesirable effect that the entire row must be reprogrammed following an erase operation.

Referring to FIG. 2, the Caywood approach is illustrated in general terms for a single memory transistor 1. The N-well 3 is created within a P-type substrate 2. The P-channel for the drain 4 and source 5 is created within the N-well 3. Poly 1 or the floating gate 6 of the memory transistor 1 is created after the active region for the drain 4 and source 5. Poly 2 or the control electrode 7 of the memory transistor is fabricated over the floating gate. Various non-conductive layers 8 insulate the P-channel 4 and 5, the floating gate 6 and the control electrode 7 from each other.

FIG. 3 illustrates a plurality of cell rows 100, typically connected to gate electrodes of memory transistors and a plurality of columns 200 typically connected to source and drain electrodes of memory transistors in the array, with both cell rows and cell columns existing on a single N-well 300 substrate. The limitation to the Caywood P-channel memory arrays, as shown in FIG. 3, is that all memory cells in any particular row must be selected, thus written or erased, during a particular operation.

Alternatively stated, as disclosed by Caywood, the cell rows are not segmented such that some memory cells in the cell row may be selected for writing while other memory cells in the row are not. Thus, in order to program the contents of a single memory cell, the entire cell row must then be programmed in order to change the data in one memory cell.

In many applications it is desired to change the data in the memory array, one byte at a time. In the N-channel device prior art, this feature was accomplished by the inclusion of a byte select transistor (BYTE) for each eight memory transistors as shown in FIG. 1. The disadvantage of this approach is the increased demand for silicon area to accommodate the overhead of the byte select transistor (BYTE). For example, from solely a transistor perspective, a byte select transistor (BYTE) for every eight memory transistors requires an 11 percent overhead (e.g., 1/9).

Moreover, the capability of changing one byte at a time would give an endurance advantage over row select memory arrays because only one byte of cells would need to undergo the electrical stress of the programming cycle as opposed to the entire row. It is well known to those skilled in the art of semiconductor memory fabrication that one cause of EEPROM failure is attributable to excessive erase/write operations.

### SUMMARY

Advantages of N-channel/P-well EEPROM technology are maximized by providing independently programmable memory segments within the EEPROM array other than with byte select transistors. This may be accomplished by providing an N-channel/P-well electrically erasable programmable read only memory array that is divided into independently programmable memory segments within a memory array by fabricating a plurality of P-wells within a deep N-well of the array or by segmenting the P-well of the array into sub-P-wells in the deep N-well. The independently programmable memory segments are achieved without the necessity for byte select transistors. Creating a plurality of P-wells within a deep N-well may be done with p-n junction isolation. Segmenting a P-well of the memory array may done by dielectric isolation.

According to a specific example embodiment of the present disclosure, a memory array comprises a plurality of P-wells within a deep N-well that is in a P-type substrate and each of the plurality of P-wells comprises a plurality of independently programmable memory segments. Each independently programmable memory segment is comprised of M memory cell columns and N memory cell rows. Each independently programmable memory segment resides within a unique and separate P-well. Thus, each P-well contains an independently programmable memory segment.

According to another specific example embodiment of the present disclosure, a memory array comprises a P-well within a deep N-well that is within a P-type substrate wherein the P-well is segmented into a plurality of electrically isolated sub P-wells, M memory transistor columns within each of the plurality of electrically isolated sub P-wells and N memory transistor rows within each of the plurality of electrically isolated sub P-wells.

Commonly owned U.S. Pat. Nos. 6,222,761 B1; 6,236,595 B1; 6,300,183 B1; and 6,504,191 B2; all by Gerber et al., disclose PMOS EEPROM having independently programmable memory segments, all of which are incorporated by reference herein for all purposes.

### BRIEF DESCRIPTION OF THE DRAWINGS

A more complete understanding of the present disclosure thereof may be acquired by referring to the following description taken in conjunction with the accompanying drawings wherein:

FIG. 1 is a schematic diagram of byte selectable N-channel memory cells in a related technology incorporating byte select transistors and row select transistors;

FIG. 2 is a cross section of a related technology P-channel memory transistor;

FIG. 3 is an illustration of a related technology in which the matrix of P-channel memory transistors resides in a single N-well;

FIG. 4 is an illustration of an N-channel memory array comprising two P-wells within a deep N-well and each P-well having an independently programmable memory segment, according to a specific example embodiment of the present disclosure;

FIG. 5 is a schematic cross section elevational view of the specific example embodiment for a plurality of P-wells within a deep N-well as illustrated in FIG. 4;

FIG. 6 is a schematic cross section elevational view of a specific example embodiment of P-well segmentation trenching of N-wells illustrated in FIG. 4;

FIG. 7 is a schematic circuit diagram of the N-channel memory array illustrated in FIG. 4, according to a specific example embodiment of the present disclosure;

FIG. 8 is a voltage matrix chart for a byte erase operation of the N-channel memory array circuit illustrated in FIG. 7;

FIG. 9 is a voltage matrix chart for a bit program operation of the N-channel memory array circuit illustrated in FIG. 7; and

FIG. 10 is a voltage matrix chart for a byte read operation of the N-channel memory array circuit illustrated in FIG. 7.

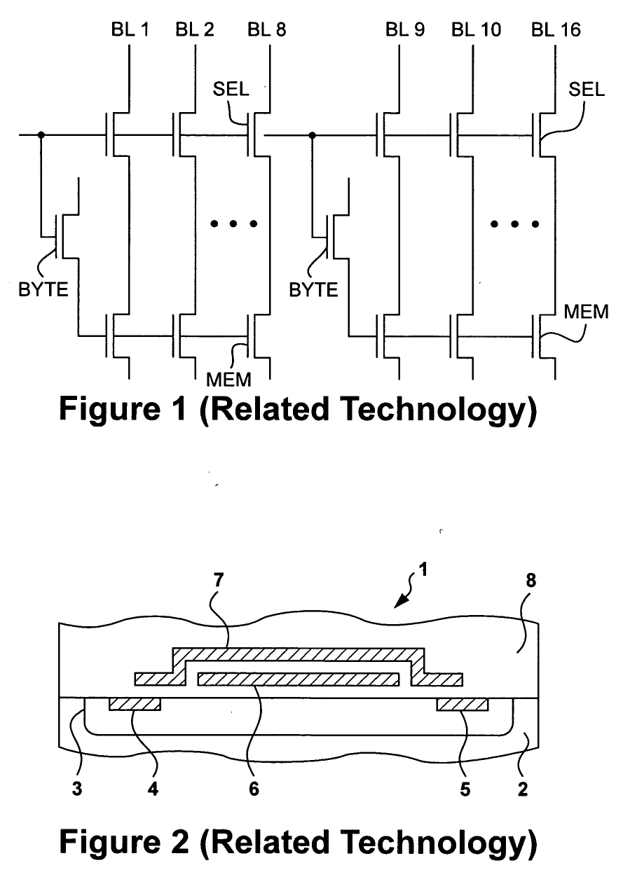

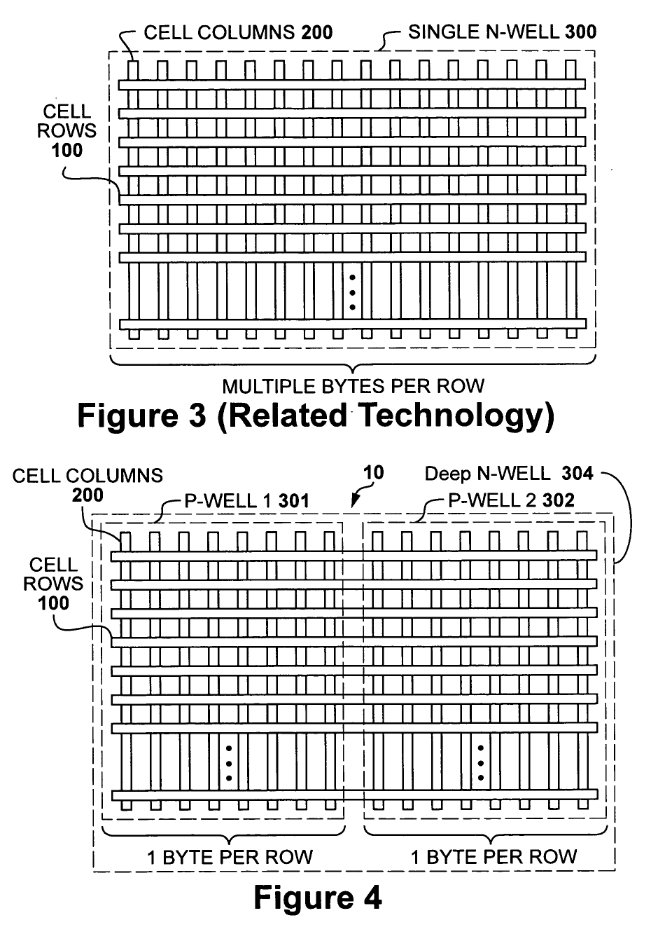

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of example embodiments are schematically illustrated. Like elements in the drawings will be represented by like numbers, and similar elements will be represented by like numbers with a different lower case letter suffix.

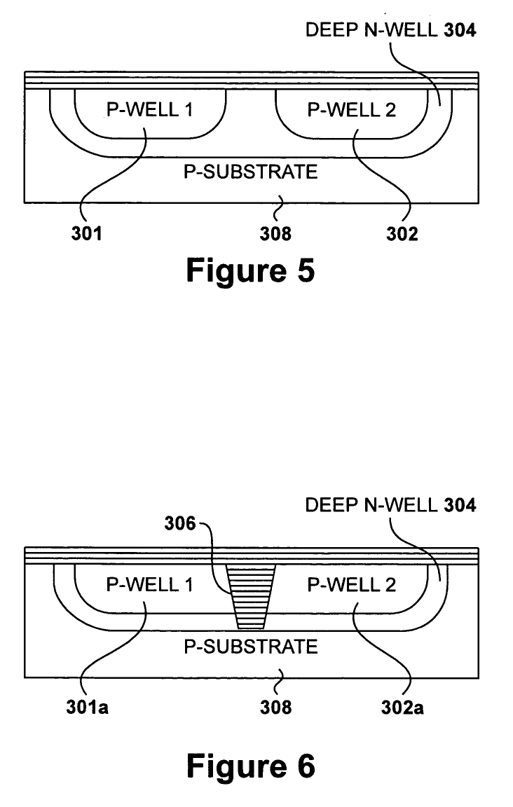

Referring to FIG. 4, an N-channel memory array 10 comprising a plurality of P-wells (e.g., 301 and 302) within a deep N-well 304 (e.g., see FIGS. 5 and 6) and a plurality of independently programmable memory segments are shown. Each independently programmable memory segment is comprised of a matrix of memory cell transistors shown as cell rows 100 and cell columns 200. The embodiment of FIG. 4 segments the 16 cell columns 200 and the plurality of cell rows 100 of the memory array 10 into two independently programmable memory segments residing within the P-wells 301 and 302, respectively, and shown in dashed lines. P-wells 301 and 302 are electrically separated from each other.

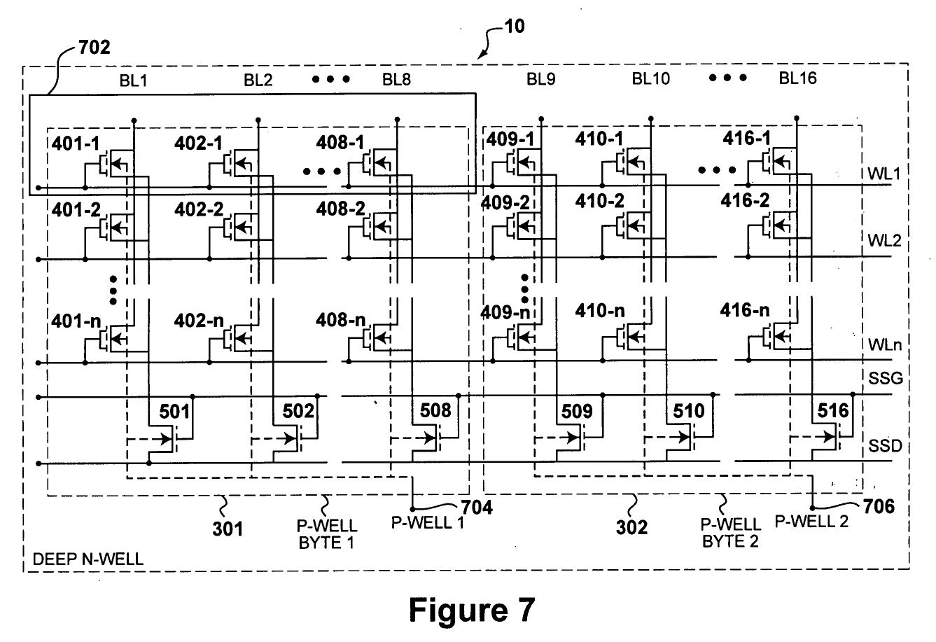

In the specific example embodiment of the present disclosure, there are eight memory transistor columns within each P-well segment, thereby comprising byte (8 bit) segments. There are a common number of cell rows 100 within each P-well and the total number of rows 100 is determined by the desired size of the memory array 10. In FIG. 4, N rows of memory transistors are illustrated. Not shown in FIG. 4, but discussed below and shown in subsequent diagrams, are source select transistors (see source select transistors 501-516 in FIG. 7) at the bottom of each column 200 of the array 10.

In the embodiment of FIG. 4 only two P-wells and two independently programmable memory segments are shown in byte format, e.g., 8 cell columns per memory segment, or a total of 16 cell columns. However, those skilled in the art will recognize that additional P-well segmentations are possible thus yielding additional independently programmable memory segments in byte format. Thus, for a byte format memory array 10, the number of independently programmable memory segments multiplied by eight, e.g., the number of cell columns 200 per memory segment, equals the total number of cell columns 200 in the array 10.

Furthermore, each of the independently programmable memory segments which may be comprised of M cell columns, where M is either smaller or larger than a byte. The number M of cell columns 200, alternative to the byte format, include, but are not limited to: 2, 4, 16, 32, 64, etc., cell columns 200 for each independently programmable memory segment. These various memory array 10 geometries are easily implemented according to the specific example embodiments of this disclosure.

Each independently programmable memory segment may be comprised of a plurality of independently programmable memory units. An independently programmable memory unit is defined as those cell columns 200 which are common to a given cell row 100 and within a single independently programmable memory segment. The intersection of a cell column 200 and a cell row 100 defines a memory cell which may be a single memory transistor. Thus, for the specific example embodiment geometry illustrated in FIG. 4, each independently programmable memory unit is comprised of eight memory cells. Furthermore, the total number of independently programmable memory units for a given independently programmable memory segment is equal to the total number (N) of cell rows 100.

The functional relevance of the independently programmable memory unit may be as follows. A single independently programmable memory unit defines the smallest or most narrow portion of the memory array 10 that may be addressed by the write and erase memory operations described below. Additionally, all independently programmable memory units within a common cell row 100 may be simultaneously addressed by the read, write and erase memory operations.

Referring to FIG. 5, depicted is a schematic cross section elevational view of the specific example embodiment for a plurality of P-wells within a deep N-well as illustrated in FIG. 4. P-well 301 and P-well 302 are formed in a deep N-well 304. The deep N-well 304 is formed in a P-type substrate 308.

Referring to FIG. 6, depicted is a schematic cross section elevational view of a specific example embodiment of P-well segmentation trenching of N-wells illustrated in FIG. 4. P-well 301a and P-well 302a are formed by dividing a single P-well with a trench 306 extending into the deep N-well 304 and filled with an insulating material. The deep N-well 304 is formed in a P-type substrate 308.

Referring to FIG. 7, depicted is a schematic circuit diagram of the N-channel memory array illustrated in FIG. 4, according to a specific example embodiment of the present disclosure. The memory array 10 is comprised of a plurality of N channel memory transistors 401-1 to 416-n which are laid out in a typical column/row matrix. Also shown are a row of N-channel source select transistors 501-516. Only one source select transistor 501-516 is necessary for each bit line BL1-BL16.

Two separate P-wells with accompanying independently programmable memory segments are shown in dashed lines drawn around a group of cells. Contained within P-well 301 are 8 memory transistor columns (only three are shown for clarity) and N memory transistor rows. P-well 302 is identical to P-well 301, however, P-well 302 is electrically isolated from P-well 301. Note that each independently programmable memory segment corresponds to a P-well and thus, the quantity of P-wells is equal to the quantity of independently programmable memory segments. The upper left independently programmable memory unit in P-well 301 is enclosed in a solid line box 702 to indicate that this is the target independently programmable memory unit (e.g., target byte) for the write, erase, and read operations described herein below.

The control electrodes of the N-channel memory transistors 401-1 to 416-n for each row are connected to common word lines WL1 to WLn, respectively. The drain electrodes of the memory transistors of any particular column are connected to a common bit lines BL1-BL16, respectively. The source electrodes of each memory transistor in a particular column are commonly connected to a respective one of the source select transistors 501-516. The source select transistors 501-516 are controlled by two control lines, SSG and SSD, connected to the gates and drains, respectively, of the source select transistors 501-516. Voltage potentials at P-well 301 and P-well 302 may also be independently controlled, as represented by node 704 and 706, respectively.

In this disclosure the IEEE standard 1005 will be followed for consistent nomenclature. Writing or programming a memory cell bit is defined as placing electrons, e.g., a charge, onto the floating gate of the memory transistor. Erasing is defined as removing electrons from the floating gate of the memory transistor. The various writing, erasing and reading operations are performed by applying different combinations of voltages onto the word lines WLx, bit lines BLx, source select transistor gates SSG, source select transistor drains SSD, and P-wells, as described herein more fully below.

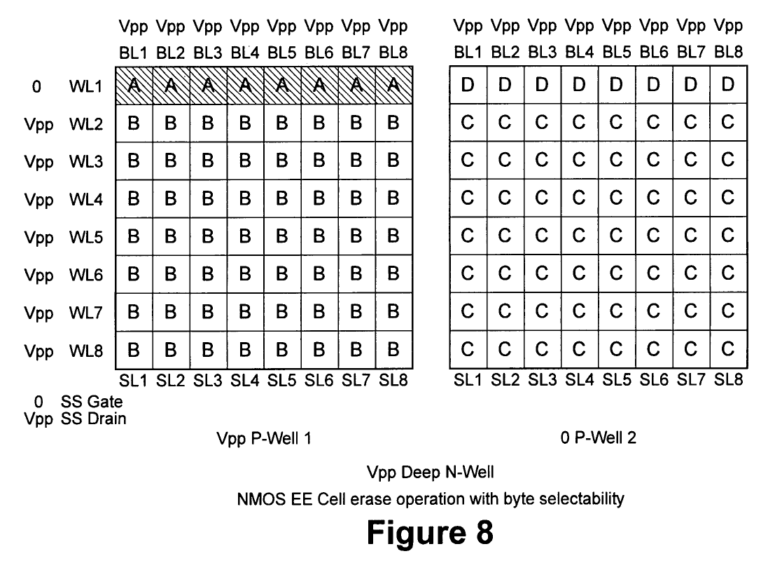

Referring to FIG. 8, depicted is a voltage matrix chart for a byte erase operation of the N-channel memory array circuit illustrated in FIG. 7. For an erase operation, the word line WLx may be either at ground potential, e.g., zero volts, or at some relatively high programming voltage Vpp, e.g., typically 12-20 volts. For erasing the target independently programmable memory unit (e.g., target byte), the gates of the memory transistors 401-1 to 416-1 (FIG. 7) are driven to substantially 0 volts over the WL1 control line. The electric field resulting from a relatively high voltage potential, in relation to the P-well 301 biased to Vpp, causes electrons to tunnel from the floating gate across the dielectric layer to the P-well of the transistors 401-1 to 408-1 (FIG. 7), thus erasing the transistors 401-1 to 408-1 (FIG. 7).

Conversely, using WL2 as an example, the P-well 301 and the control electrodes of memory transistors 401-2 to 408-2 are biased to Vpp. Under these conditions, no tunneling occurs because of an absence of an electric field between these memory transistors 401-2 to 408-2 and the P-well 301. Thus, memory transistors 401-2 to 408-2 are not erased.

With respect to memory transistors 409-2 to 416-2, the P-well 302 is at substantially ground or zero volts and the control electrodes at Vpp potential results in a N-type inversion layer under the poly 2 layer of each of the memory cells 409-2 to 416-2. With BL9-16 at Vpp and the drain electrodes of memory transistors 409-2 to 416-2 tied to the inversion layer, there is no voltage potential between the control electrode and the inversion layer at the surface of the P-well 302. Thus, even with the P-well 302 biased to substantially ground or zero volts, no tunneling occurs thereby precluding an erase operation for memory transistors 409-2 to 416-2.

For the erase operation, the bit line to each of the columns BL1:8 and BL9:16 are set to Vpp, SSG is set to substantially ground or zero volts, SSD is set to Vpp, and the P-well 301 is biased to Vpp. This permits a sufficient voltage potential between the floating gate of the memory transistors 401-1 to 408-1, controlled by WL1 and the P-well 301. Electrons tunnel from the floating gate across the dielectric layer to the P-well 301, thus positively charging the floating gate. Conversely, P-well 302 is biased to substantially ground or zero volts, thereby failing to create the sufficient voltage potential between the control electrodes of the memory transistors 409-1 to 416-1 that are within P-well 302 and the P-well 302. Without a sufficient voltage differential, tunneling cannot occur and the erase cycle is not accomplished. Thus, by providing for separate and isolated P-wells, the N-channel memory transistors in any row may be organized in byte selectable segments where byte selection is effected, at least in part, by the application of, or biasing at, different voltage potentials, the plurality of the P-wells themselves.

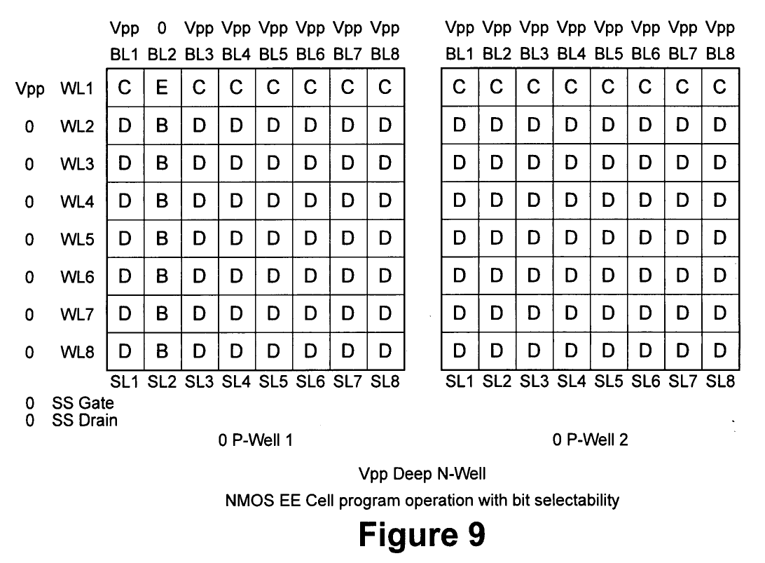

Referring to FIG. 9, depicted is a voltage matrix chart for a bit program operation of the N-channel memory array circuit illustrated in FIG. 7. In this example, word line WL1 is set to Vpp, which capacitively couples the floating gates of the memory transistors 401-1 through 416-1 to a high voltage and turns these transistors on hard, thereby creating an inversion layer. The remainder of the word lines WL2:n, the select lines SSG and SSD, and P-wells 301 and 302 are biased to substantially ground or zero volts. Bit line BL2 is biased to substantially ground or zero volts while BL1 and BL3:8 are set to Vpp for P-well 301. This causes the inversion layer under the floating gate and pass gate of transistor 402-1 to be biased at 0 volts. This causes electron tunneling from the inversion region in the P-well 301 to the floating gate of the transistor 402-1 and thus charges the floating gate of the memory transistor 402-1, but not the other floating gates (refer to FIG. 7).

Conversely, with WL1, BL1, and BL3:16 set to Vpp, the inversion layer for memory transistors 401-1 and 403-1 to 416-1 is biased at Vpp, which results in substantially no electron tunneling. Thus, the write operation is not accomplished for memory transistors 401-1 and 403-1 to 416-1. In the target independently programmable memory unit (e.g., target byte 702) of FIG. 7, identified by the bolded rectangle, a binary pattern may be entered into the memory cells 401-1 through 408-1 by setting bit lines BL1-BL8 to either zero volts or Vpp. Bit lines set to substantially ground or zero volts will write the memory cell. Bit lines set to Vpp will remain in an unchanged state.

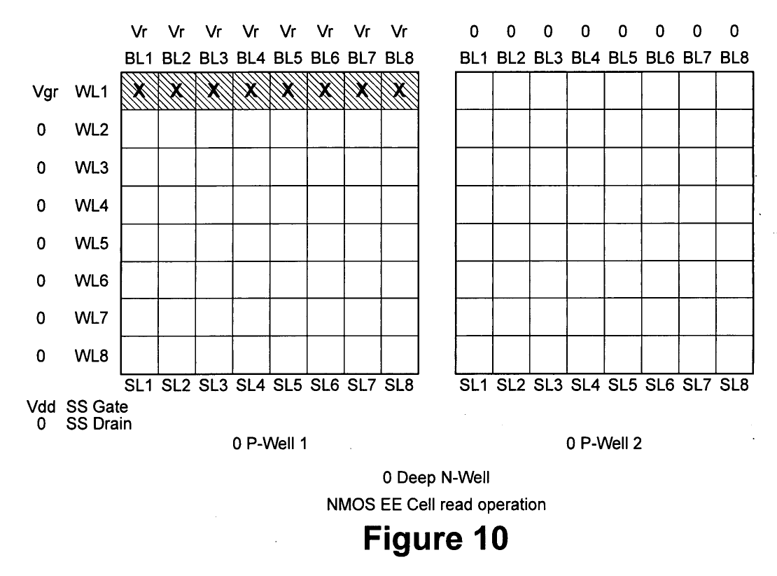

Referring to FIG. 10, depicted is a voltage matrix chart for a byte read operation of the N-channel memory array circuit illustrated in FIG. 7. In this example, WL1 is set to VGR, a voltage between VDD and ground, sufficient to turn on memory transistors 401-1 to 416-1. Word lines WL2:n are set to substantially ground or zero volts which turn off the remainder of the memory transistors. The P-wells 301 and 302 are also set to substantially ground or zero volts which is a normal “body bias” for a N-channel transistor in CMOS technology. SSG is set to VDD and SSD is set to substantially ground or zero volts which permits the source select transistors to source current. With the above conditions set, the bit lines BL1:16 are left to control the read operation. To read the target independently programmable memory unit, BL1:BL8 are set to VR (VR may be in a range from about 1.0 to 2.5 volts) which creates a voltage potential between the source and drain of the memory transistors resulting in a current that may be read by the sense amplifiers (not shown). BL9:16 are set to substantially ground or zero volts, thereby not creating the requisite voltage potential between source and drain and thus, inhibiting the memory read of that byte.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and finction, as will occur to those ordinarily skilled in the pertinent art and having the benefit of this disclosure. The depicted and described embodiments of this disclosure are examples only, and are not exhaustive of the scope of the disclosure.

1. An electrically erasable programmable read only memory array, comprising:
at least two P-wells in a deep N-well within a P-type substrate, wherein said at least two P-wells are electrically isolated from each other and thereby capable of being at different voltages;
a plurality of independently programmable memory segments in each of said at least two P-wells; and
a plurality of independently programmable memory units in each of said plurality of independently programmable memory segments, wherein a one of said plurality of independently programmable memory units is programmable within a respective one of said at least two P-wells.

2. The electrically erasable programmable read only memory array according to claim 1, wherein said one of said plurality of independently programmable memory units is defined as M memory cell columns in common with a memory cell row which are within said respective one of said at least two P-wells.

3. The electrically erasable programmable read only memory array according to claim 2, wherein M is equal to eight.

4. The electrically erasable programmable read only memory array according to claim 2, wherein M is equal to 2ⁿ, where n is a non-negative integer number.

5. The electrically erasable programmable read only memory array according to claim 1, wherein each of said plurality of independently programmable memory segments comprises: M memory cell columns located within each of said at least two P-wells; and N memory cell rows located within each of said at least two P-wells.

6. The electrically erasable programmable read only memory array according to claim 5, wherein M is equal to eight and N is equal to 2ⁿ, where n is a positive integer number.

7. The electrically erasable programmable read only memory array according to claim 1, wherein each of said at least two P-wells may be independently biased to different voltage levels.

8. The electrically erasable programmable read only memory array according to claim 1, wherein each of said plurality of independently programmable memory segments further comprises a plurality of select transistors.

9. The electrically erasable programmable read only memory array according to claim 1, wherein each of said plurality of independently programmable memory segments comprises: a plurality of memory cell columns located within a one of said at least two P-wells; and a memory cell row located within the one of said at least two P-wells.

10. An electrically erasable programmable read only memory array, comprising:
a P-well located in a deep N-well that is within a P-type substrate, said P-well being segmented into a plurality of electrically isolated sub-P-wells that are electrically isolated from each other and thereby capable of being at different voltages;
a plurality of independently programmable memory segments in each of said plurality of sub-P-wells; and
a plurality of independently programmable memory units in each of said plurality of independently programmable memory segments, wherein a one of said plurality of independently programmable memory units is programmable within a respective one of said plurality of sub-P-wells.

11-30. (canceled)

31. The electrically erasable programmable read only memory array according to claim 1, wherein a one of said at least two P-wells is biased to a relatively high voltage potential to effect a write operation on a one of said plurality of independently programmable memory segments within said one of said at least two P-wells that is biased to a relatively high voltage potential.

32. The electrically erasable programmable read only memory array according to claim 31, wherein the other ones of said at least two P-wells are biased to approximately ground potential for inhibiting a write operation on each of said plurality of independently programmable memory segments within the other ones of said at least two P-wells.

33. The electrically erasable programmable read only memory array according to claim 1, wherein said one of said plurality of independently programmable memory units may be written to while another one of said plurality of independently programmable memory units in another one of said at least two P-wells may be erased.
